(19) United States
(12) Patent Application Publication
(10) Pub. No.: US 2009/0294949 A1
(43) Pub. Date: Dec. 3, 2009

(54) MOLDED SEMICONDUCTOR DEVICE

(75) Inventor: Thorsten Meyer, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies AG, Neubiberg, DE (US)

(21) Appl. No.: 12/130,138

(22) Filed: May 30, 2008

(51) Int. Cl. H01L 23/49; H01L 21/02

(52) U.S. Cl. 257/690; 257/738; 438/127; 257/E21.536; 257/E23.141

(57) ABSTRACT

A semiconductor device includes a semiconductor chip and at least one metal line over a first side of the semiconductor chip. The semiconductor device includes a molded body covering at least a second side of the semiconductor chip. The molded body includes at least one recess.

### BACKGROUND

Embedded wafer level ball grid array (eWLB) technology expands on typical wafer level packaging technologies. Semiconductor devices fabricated using eWLB technology typically include a semiconductor chip or die electrically coupled to an array of solder balls or bumps through a redistribution layer. Opposite the redistribution layer and the array of solder balls, a mold material or compound typically encapsulates the semiconductor chip. The use of semiconductor devices fabricated using eWLB technology continues to expand into new applications.

For these and other reasons, there is a need for the present invention.

### SUMMARY

One embodiment provides a semiconductor device. The semiconductor device includes a semiconductor chip and at least one metal line over a first side of the semiconductor chip. The semiconductor device includes a molded body covering at least a second side of the semiconductor chip. The molded body includes at least one recess.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross-sectional view of one embodiment of a semiconductor device.

FIG. 2 illustrates a cross-sectional view of another embodiment of a semiconductor device.

FIG. 3 illustrates a cross-sectional view of another embodiment of a semiconductor device.

FIG. 4 illustrates a cross-sectional view of another embodiment of a semiconductor device.

FIG. 5 illustrates a cross-sectional view of another embodiment of a semiconductor device.

FIG. 6 illustrates a cross-sectional view of another embodiment of a semiconductor device.

FIG. 7 illustrates a cross-sectional view of another embodiment of a semiconductor device.

FIG. 8 illustrates a cross-sectional view of another embodiment of a semiconductor device.

FIG. 9 illustrates a cross-sectional view of another embodiment of a semiconductor device.

FIG. 10 illustrates a cross-sectional view of another embodiment of a semiconductor device.

FIG. 11 illustrates a perspective view of another embodiment of a semiconductor device.

FIG. 12 illustrates a cross-sectional view of one embodiment of a carrier.

FIG. 13 illustrates a cross-sectional view of one embodiment of the carrier and a double-sided adhesive foil.

FIG. 14 illustrates a cross-sectional view of one embodiment of the carrier, the double-sided adhesive foil, and semiconductor chips.

FIG. 15 illustrates a cross-sectional view of one embodiment of the carrier, the double-sided adhesive foil, the semiconductor chips, and a mold compound in a molding tool.

FIG. 16 illustrates a cross-sectional view of one embodiment of the carrier, the double-sided adhesive foil, the semiconductor chips, and the mold compound in the molding tool.

FIG. 17 illustrates a cross-sectional view of one embodiment of the carrier, the double-sided adhesive foil, the semiconductor chips, and the mold compound.

FIG. 18 illustrates a cross-sectional view of one embodiment of the semiconductor chips and the mold compound after the release of the carrier and the double-sided adhesive foil.

FIG. 19 illustrates a cross-sectional view of one embodiment of multiple semiconductor devices prior to separation.

FIG. 20 illustrates a cross-sectional view of another embodiment of a semiconductor device.

FIG. 21 illustrates a cross-sectional view of another embodiment of a semiconductor device.

FIG. 22 illustrates a cross-sectional view of another embodiment of a semiconductor device.

FIG. 23 illustrates a cross-sectional view of another embodiment of a semiconductor device.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

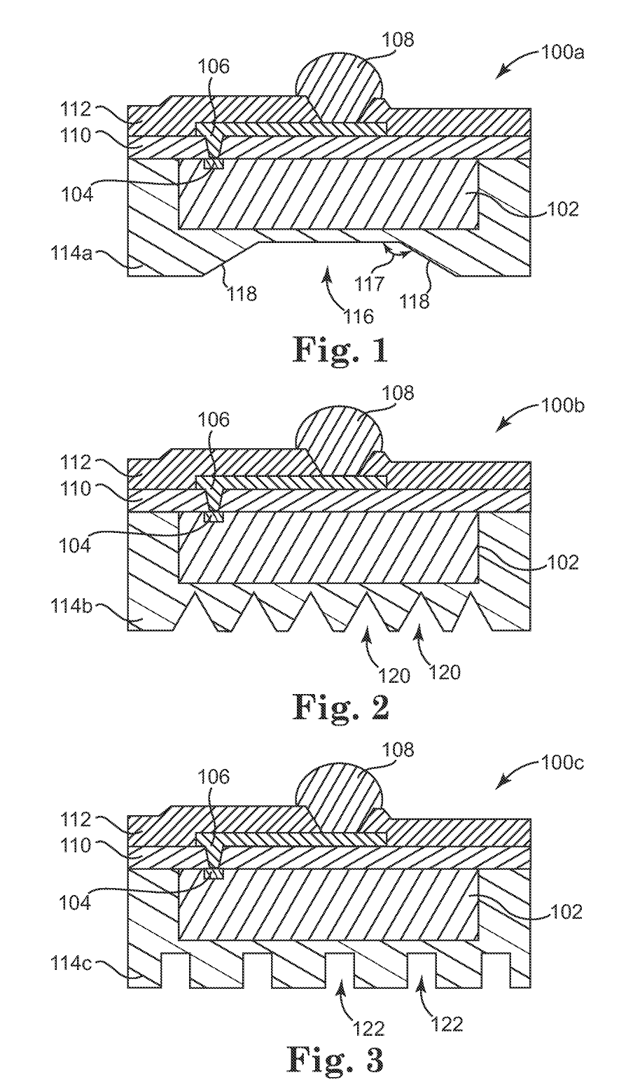

FIG. 1 illustrates a cross-sectional view of one embodiment of a semiconductor device 100a. Semiconductor device 100a is fabricated using a wafer level packaging process. Semiconductor device 100a includes a semiconductor chip or die 102 including circuitry (not shown) and a contact pad 104. Semiconductor device 100a includes a dielectric material layer 110, a redistribution line 106, a solder stop material layer 112, a solder ball or bump 108, and a molded body 114a. Semiconductor device 100a includes only a single contact pad 104, redistribution line 106, and solder ball or bump 108 for simplicity. In other embodiments, however, semiconductor device 100a includes any suitable number of contact pads 104, redistribution lines 106, and solder balls or bumps 108.

A first side of semiconductor chip 102 contacts molded body 114a. Molded body 114a at least partially encapsulates semiconductor chip 102. In one embodiment, molded body 114a includes a mold material or compound and is fabricated using a molding process. Molded body 114a includes a recess 116 including sidewalls 118. In one embodiment, sidewalls 118 are slanted such that angle 117 is greater than 90° and recess 116 has a trapezoidal shape. In another embodiment, sidewalls 118 are vertical such that angle 117 is approximately 90° and recess 116 has a rectangular shape. Recess 116 is configured for mechanically coupling semiconductor device 100a to another object. In one embodiment, the object is another semiconductor device, a cooling structure, a mounting structure, or another suitable object. In one embodiment, recess 116 provides a mechanical stop.

A second side of semiconductor chip 102 opposite the first side of semiconductor chip 102 contacts a first side of dielectric material layer 110 and a portion of redistribution line 106. Dielectric material layer 110 includes a polyimide or another suitable dielectric material. A second side of dielectric material layer 110 contacts a first side of redistribution line 106 and a portion of a first side of solder stop material layer 112. Redistribution line 106 includes Cu or another suitable conductive material or conductive material stack. Solder stop material layer 112 contacts a second side of redistribution line 106 and supports solder ball 108. Solder stop material layer 112 includes a polyimide or another suitable dielectric material. Solder ball 108 is electrically coupled to contact pad 104 of semiconductor chip 102 through redistribution line 106. In one embodiment, semiconductor chip 102 includes a Si substrate or another suitable substrate. Contact pad 104 includes Al or another suitable contact material.

FIG. 2 illustrates a cross-sectional view of another embodiment of a semiconductor device 100b. Semiconductor device 100b is similar to semiconductor device 100a previously described and illustrated with reference to FIG. 1, except that in semiconductor device 100b, molded body 114a is replaced with molded body 114b. In one embodiment, molded body 114b includes a mold compound and is fabricated using a molding process. Molded body 114b includes a plurality of recesses 120. In one embodiment, each recess 120 has a triangular shape. Recesses 120 are configured for mechanically coupling semiconductor device 100b to another object. In one embodiment, the object is another semiconductor device, a cooling structure (e.g., cooling fins, cooling web), a mounting structure (e.g., clamp), or another suitable object. In one embodiment, recesses 120 provide a mechanical stop.

FIG. 3 illustrates a cross-sectional view of another embodiment of a semiconductor device 100c. Semiconductor device 100c is similar to semiconductor device 100a previously described and illustrated with reference to FIG. 1, except that in semiconductor device 100c, molded body 114a is replaced with molded body 114c. In one embodiment, molded body 114c includes a mold compound and is fabricated using a molding process. Molded body 114c includes a plurality of recesses 122. In one embodiment, each recess 122 has a square or rectangular shape. Recesses 122 are configured for mechanically coupling semiconductor device 100c to another object. In one embodiment, the object is another semiconductor device, a cooling structure, a mounting structure (e.g., a structure with holes), or another suitable object. In one embodiment, recesses 122 provide single or multiple mechanical edge guides and/or a mechanical stop.

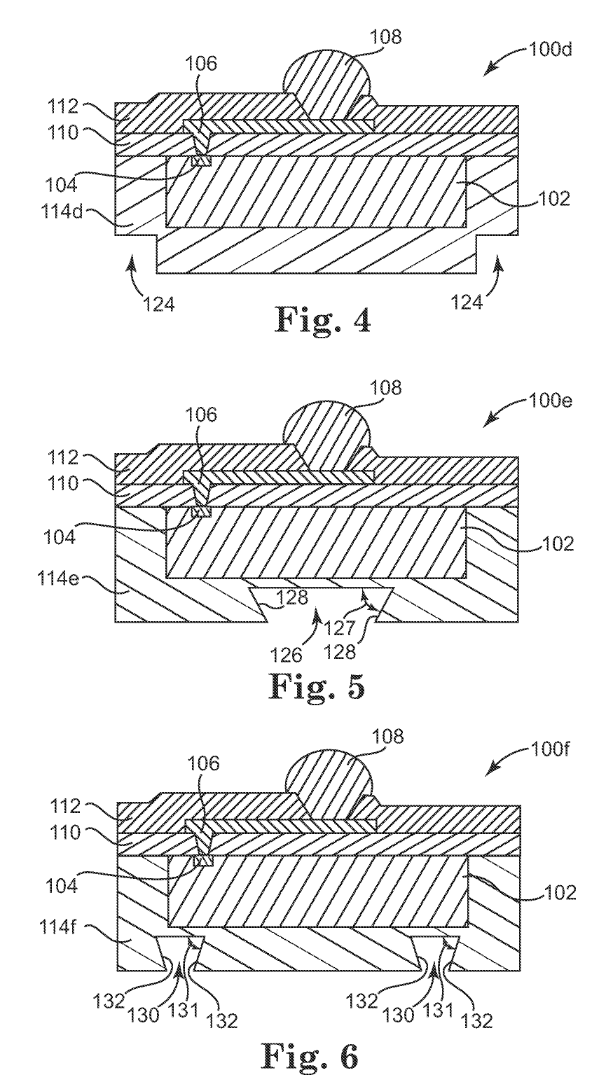

FIG. 4 illustrates a cross-sectional view of another embodiment of a semiconductor device 100d. Semiconductor device 100d is similar to semiconductor device 100a previously described and illustrated with reference to FIG. 1, except that in semiconductor device 100d, molded body 114a is replaced with molded body 114d. In one embodiment, molded body 114d includes a mold compound and is fabricated using a molding process. Molded body 114d includes at least two recesses 124. In one embodiment, each recess 124 is at a corner of molded body 114d and has a square or rectangular shape. Recesses 124 are configured for mechanically coupling semiconductor device 100d to another object. In one embodiment, the object is another semiconductor device, a cooling structure, a mounting structure (e.g., a structure with a press fit opening), or another suitable object. In one embodiment, recesses 124 provide a mechanical edge guide and/or a mechanical stop.

FIG. 5 illustrates a cross-sectional view of another embodiment of a semiconductor device 100e. Semiconductor device 100e is similar to semiconductor device 100a previously described and illustrated with reference to FIG. 1, except that in semiconductor device 100e, molded body 114a is replaced with molded body 114e. In one embodiment, molded body 114e includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 114e includes a recess 126 including sidewalls 128. In one embodiment, sidewalls 128 are slanted such that angle 127 is less than 90° and recess 126 has a trapezoidal shape. Recess 126 is configured for mechanically coupling semiconductor device 100e to another object. In one embodiment, the object is another semiconductor device, a cooling structure, a mounting structure (e.g., a rail, a clamp, a clip), or another suitable object.

FIG. 6 illustrates a cross-sectional view of another embodiment of a semiconductor device 100f. Semiconductor device 100f is similar to semiconductor device 100a previously described and illustrated with reference to FIG. 1, except that in semiconductor device 100f, molded body 114a is replaced with molded body 114f. In one embodiment, molded body 114f includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 114f includes at least two recesses 130 including sidewalls 132. In one embodiment, sidewalls 132 are slanted such that angle 131 is less than 90° and each recess 130 has a trapezoidal shape. Recesses 130 are configured for mechanically coupling semiconductor device 100f to another object. In one embodiment, the object is another semiconductor device, a cooling structure, a mounting structure (e.g., two parallel rails, a clamp, a clip), or another suitable object.

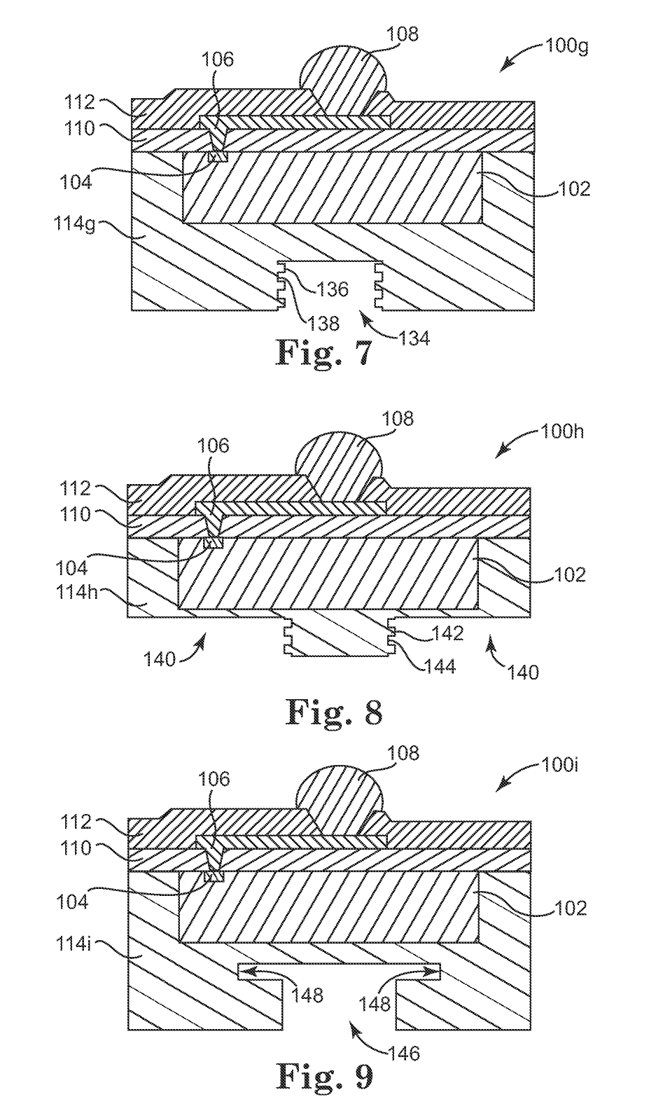

FIG. 7 illustrates a cross-sectional view of another embodiment of a semiconductor device 100g. Semiconductor device 100g is similar to semiconductor device 100a previously described and illustrated with reference to FIG. 1, except that in semiconductor device 100g, molded body 114a is replaced with molded body 114g. In one embodiment, molded body 114g includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 114g includes recess 134 including teeth or thread 136 separated by spaces 138. Recess 134 is configured for mechanically coupling semiconductor device 100g to another object. In one embodiment, the object is another semiconductor device, a cooling structure, a mounting structure (e.g., a thread, a winding, a worm), or another suitable object.

FIG. 8 illustrates a cross-sectional view of another embodiment of a semiconductor device 100h. Semiconductor device 100h is similar to semiconductor device 100a previously described and illustrated with reference to FIG. 1, except that in semiconductor device 100h, molded body 114a is replaced with molded body 114h. In one embodiment, molded body 114h includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 114h includes recesses 140, which define teeth or thread 142 separated by spaces 144. Recesses 140 are configured for mechanically coupling semiconductor device 100h to another object. In one embodiment, the object is another semiconductor device, a cooling structure, a mounting structure (e.g., a thread, a winding), or another suitable object.

FIG. 9 illustrates a cross-sectional view of another embodiment of a semiconductor device 100i. Semiconductor device 100i is similar to semiconductor device 100a previously described and illustrated with reference to FIG. 1, except that in semiconductor device 100i, molded body 114a is replaced with molded body 114i. In one embodiment, molded body 114i includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 114i includes recess 146, which includes openings 148, such that recess 146 is T-shaped. Recess 146 is configured for mechanically coupling semiconductor device 100i to another object. In one embodiment, the object is another semiconductor device, a cooling structure, a mounting structure (e.g., a clamp, a clip), or another suitable object.

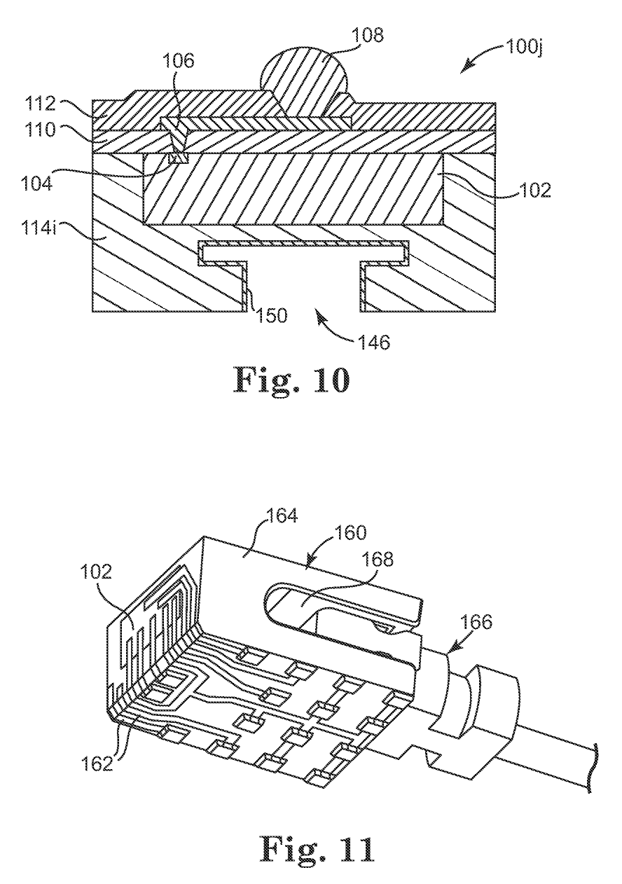

FIG. 10 illustrates a cross-sectional view of another embodiment of a semiconductor device 100j. Semiconductor device 100j is similar to semiconductor device 100i previously described and illustrated with reference to FIG. 9, except that semiconductor device 100j also includes plated metal layer 150. In one embodiment, a metal, such as Cu, Al, or another suitable metal is electroless plated over molded body 114i in recess 146. In one embodiment, plated metal layer 150 provides a solder contact for mechanically coupling semiconductor device 100j to another object. In one embodiment, the object is another semiconductor device, a cooling structure, a mounting structure (e.g., a clamp, a clip), or another suitable object.

FIG. 11 illustrates a perspective view of another embodiment of a semiconductor device 160. Semiconductor device 160 is optically and mechanically coupled to a fiber optic cable 166. Semiconductor device 160 includes a semiconductor chip 102, a molded body 164, and conductive lines 162. Semiconductor chip 102 is electrically coupled to light emitters/detectors (not shown) through conductive lines 162. Semiconductor chip 102 is embedded or countersunk into molded body 160. Molded body 160 includes a recess 168 configured for receiving fiber optic cable 166. In one embodiment, molded body 160 includes a mold compound and is fabricated using a molding process followed by additional processing. In one embodiment, the additional processing includes laser cutting, sawing, lapping, grinding, milling, or shaping the mold compound using another suitable technique to provide recess 168.

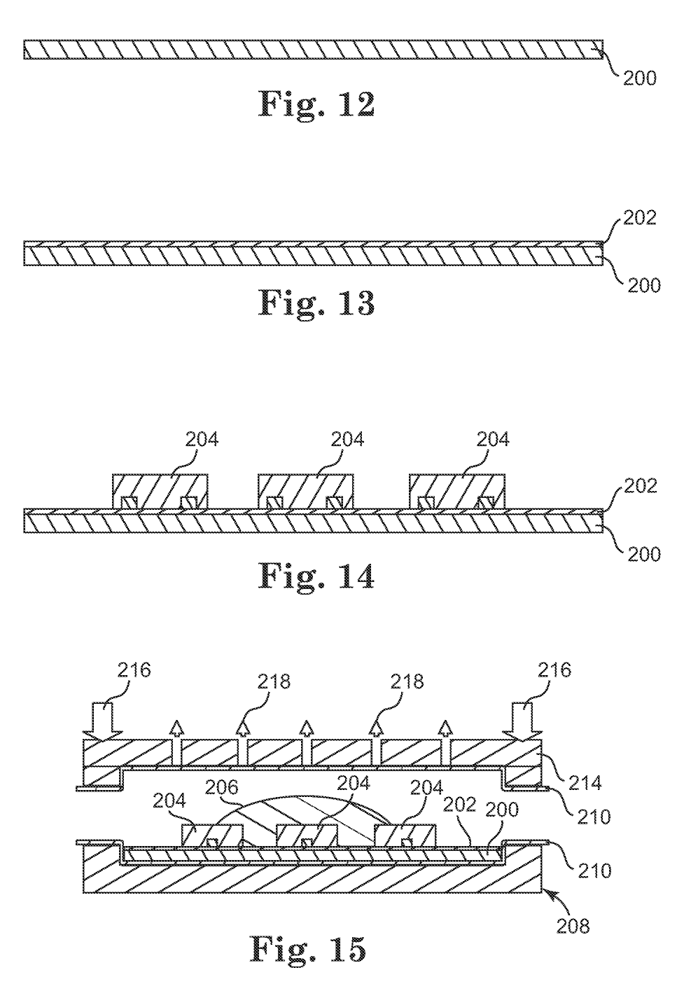

The following FIGS. 12-19 illustrate embodiments of a process for fabricating a semiconductor device, such as a semiconductor device 100a-100j or 160 previously described and illustrated with reference to FIGS. 1-11.

FIG. 12 illustrates a cross-sectional view of one embodiment of a carrier 200. Carrier 200 includes a metal, a polymer, silicon, or another suitable material.

FIG. 13 illustrates a cross-sectional view of one embodiment of carrier 200 and a double-sided adhesive foil 202. A double-sided, releasable, adhesive foil 202 is laminated to carrier 200 or applied to carrier 200 using another suitable technique. In other embodiments, other suitable adhesives are used in place of double-sided adhesive foil 202.

FIG. 14 illustrates a cross-sectional view of one embodiment of carrier 100, double-sided adhesive foil 202, and semiconductor chips 204. A plurality of semiconductor chips or dies 204 are placed on double-sided adhesive foil 202. The semiconductor chips 204 are placed on double-sided adhesive foil 202 using pick and place equipment or another suitable process.

FIG. 15 illustrates a cross-sectional view of one embodiment of carrier 200, double-sided adhesive foil 202, semiconductor chips 204, and a mold compound 206 in a molding tool 208. In one embodiment, molding tool 208 includes a top portion 214 configured to fabricate a molded body having a recess, such as a molded body 114a-114d previously described and illustrated with reference to FIGS. 1-4, respectively. In another embodiment, molding tool 208 includes a top portion 214 configured to fabricate an unfinished molded body that is later finished using additional processing to provide a molded body having a recess, such as a molded body 114e-114i previously described and illustrated with reference to FIGS. 5-9, respectively.

The inside of molding tool 208 is lined with cover tape 210, such as teflon foil or another suitable cover tape. Carrier 200, double-sided adhesive foil 202, and semiconductors chips 204 are placed into molding tool 208. A liquid mold compound 206 having a high viscosity is dispensed in the center of carrier 200. In one embodiment, molding tool 208 is heated. A vacuum as indicated by arrows 218 is applied to molding tool 208. A force as indicated by arrows 216 is then applied to begin closing top 214 of molding tool 208.

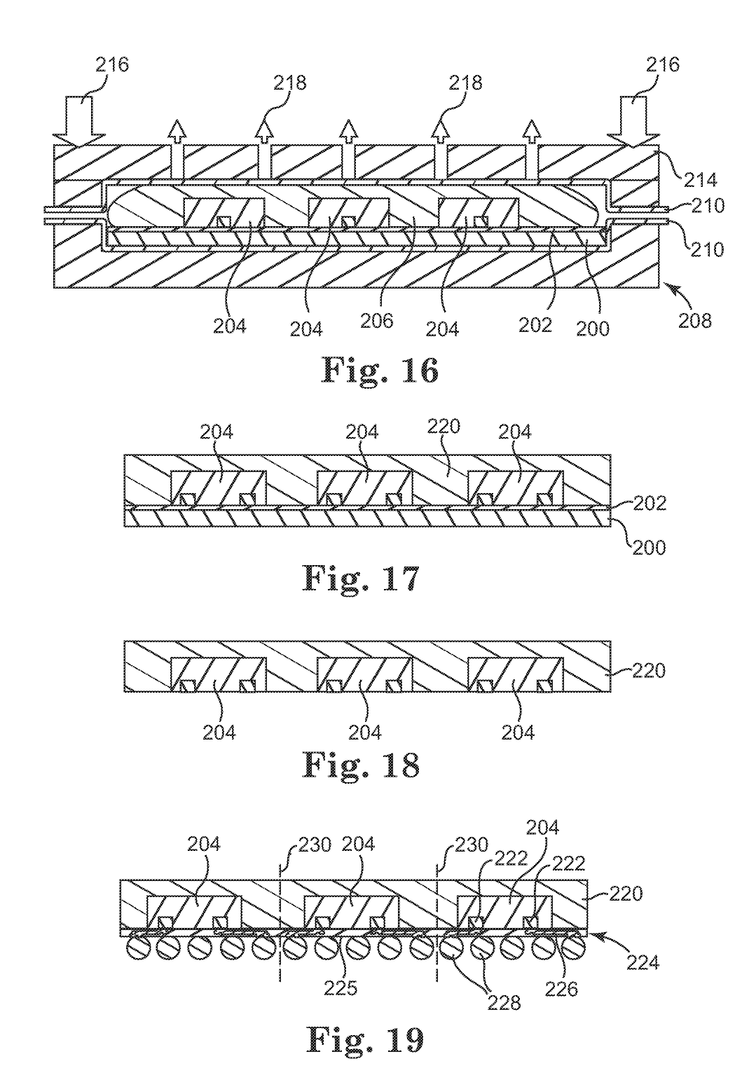

FIG. 16 illustrates a cross-sectional view of one embodiment of carrier 200, double-sided adhesive foil 202, semiconductor chips 204, and mold compound 206 in molding tool 208. Top 214 of molding tool 208 is closed forcing liquid mold compound 206 to flow from the center of molding tool 208 toward the edges of molding tool 208.

FIG. 17 illustrates a cross-sectional view of one embodiment of carrier 200, double-sided adhesive foil 202, semiconductor chips 204, and mold compound 220. Carrier 200, double-sided adhesive foil 202, semiconductor chips 204, and mold compound 220 are removed from molding tool 208 after mold compound 206 solidifies to provide mold compound 220. In one embodiment, mold compound 220 includes a recess or recesses above or near each semiconductor chip 204 for fabricating a molded body, such as a molded body 114a-114d previously described and illustrated with reference to FIGS. 1-4, respectively. In another embodiment, mold compound 220 is subjected to additional processing, such as laser cutting, sawing, lapping, grinding, milling, or shaping the mold compound using another suitable technique for fabricating a molded body, such as a molded body 114e-114i previously described and illustrated with reference to FIGS. 5-9, respectively.

FIG. 18 illustrates a cross-sectional view of one embodiment of semiconductor chips 204 and mold compound 220 after the release of carrier 200 and double-sided adhesive foil 202. Double-sided adhesive foil 202 and carrier 200 are released from semiconductor chips 204 and mold compound 220. One surface of each semiconductor chip 106 is exposed where double-sided adhesive foil 202 was previously attached. In one embodiment, mold compound 220 is subjected to additional processing, such as laser cutting, sawing, lapping, grinding, milling, or shaping the mold compound using another suitable technique for fabricating a molded body after the release of carrier 200 and double-sided adhesive foil 202.

FIG. 19 illustrates a cross-sectional view of one embodiment of multiple semiconductor devices prior to separation. A redistribution layer 224 is fabricated and solder balls 228 are applied to redistribution layer 224. Redistribution layer 224 includes redistribution lines 226 formed in a conductive layer. In one embodiment, redistribution lines 226 are metal lines and extend over semiconductor chips 204 and mold compound 220. Redistribution lines 226 electrically couple contacts 222 of each semiconductor chip 204 to solder balls 228. Redistribution layer 224 includes insulating material 225 surrounding redistribution lines 226.

In one embodiment, redistribution layer 224 is fabricated by depositing a dielectric material, such as a polyimide or another suitable dielectric material over semiconductor chips 204 and mold compound 220. The dielectric material layer is deposited using a spin-on deposition or another suitable deposition technique. The dielectric material layer is then etched to provide openings exposing at least a portion of each contact 222. The openings are patterned using a photolithography process or another suitable process.

A conductive material, such as TiW or another suitable conductive material is conformally deposited over exposed portions of the dielectric material layer and contacts 222 to provide a conductive material layer. The conductive material layer is deposited using a sputter deposition or another suitable deposition technique. In one embodiment, the conductive material layer is deposited to a thickness of approximately 50 nm or another suitable thickness.

A seed material, such as Cu or another suitable seed material is conformally deposited over the conductive material layer to provide a seed layer. The seed layer is deposited using a sputter deposition or another suitable deposition technique. In one embodiment, the seed layer is deposited to a thickness of approximately 150 nm or another suitable thickness. In one embodiment, the conductive material layer and the seed layer are collectively referred to as a seed layer.

A mask material, such as photoresist or another suitable mask material is deposited over the seed layer to provide a mask material layer. The mask material layer is patterned and etched to provide openings exposing portions of the seed layer where redistribution lines 226 are to be located. In one embodiment, an electroplating process is used to deposit Cu or another suitable conducting material on exposed portions of the seed layer to provide redistribution lines 226. In one embodiment, the Cu is electroplated to a thickness of approximately 6 μm or another suitable thickness.

The mask material layer is removed to expose portions of the seed layer. The exposed portions of the seed layer are etched to expose portions of the conductive material layer. The exposed portions of the conductive material layer are etched to expose the dielectric material layer. A solder stop material, such as a polyimide or another suitable dielectric material is deposited over the dielectric material and redistribution lines 226 to provide a solder stop material layer. The solder stop material layer is deposited using a spin-on deposition or another suitable deposition technique. The solder stop material layer is patterned and etched to provide openings exposing portions of redistribution lines 226 and to provide insulating material 225. Solder balls 228 are then applied to the exposed portions of redistribution lines 226.

The semiconductor devices are then separated from each other. Dashed lines 230 indicate where mold compound 220 and redistribution layer 224 are cut to separate the semiconductor devices from each other. The semiconductor devices are separated by sawing, etching, or other suitable method to provide semiconductor devices, such as semiconductor devices 100a-100j or 160 as previously described and illustrated with reference to FIGS. 1-11.

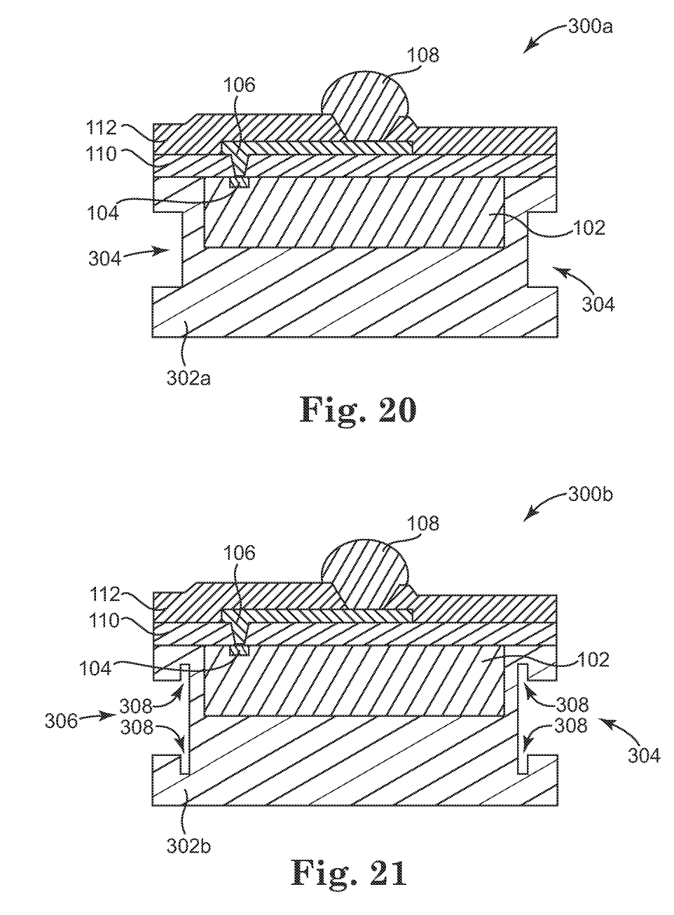

FIG. 20 illustrates a cross-sectional view of another embodiment of a semiconductor device 300a. Semiconductor device 300a is similar to semiconductor device 100a previously described and illustrated with reference to FIG. 1, except that in semiconductor device 300a, molded body 114a is replaced with molded body 302a. In one embodiment, molded body 302a includes a mold compound and is fabricated using a molding process. Molded body 302a includes at least one recess 304 on each sidewall of semiconductor device 300a. In one embodiment, each recess 304 has a square or rectangular shape. Recesses 304 are configured for mechanically coupling semiconductor device 300a to another object. In one embodiment, the object is another semiconductor device, a cooling structure, a mounting structure (e.g., a structure with holes), or another suitable object. In one embodiment, recesses 304 provide single or multiple mechanical edge guides and/or a mechanical stop.

FIG. 21 illustrates a cross-sectional view of another embodiment of a semiconductor device 300b. Semiconductor device 300b is similar to semiconductor device 100a previously described and illustrated with reference to FIG. 1, except that in semiconductor device 300b, molded body 114a is replaced with molded body 302b. In one embodiment, molded body 302b includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 302b includes at least one recess 306 on each sidewall of semiconductor device 300b. Each recess 306 includes openings 308, such that recess 306 is sideways T-shaped. Each recess 306 is configured for mechanically coupling semiconductor device 300b to another object. In one embodiment, the object is another semiconductor device, a cooling structure, a mounting structure (e.g., a clamp, a clip), or another suitable object.

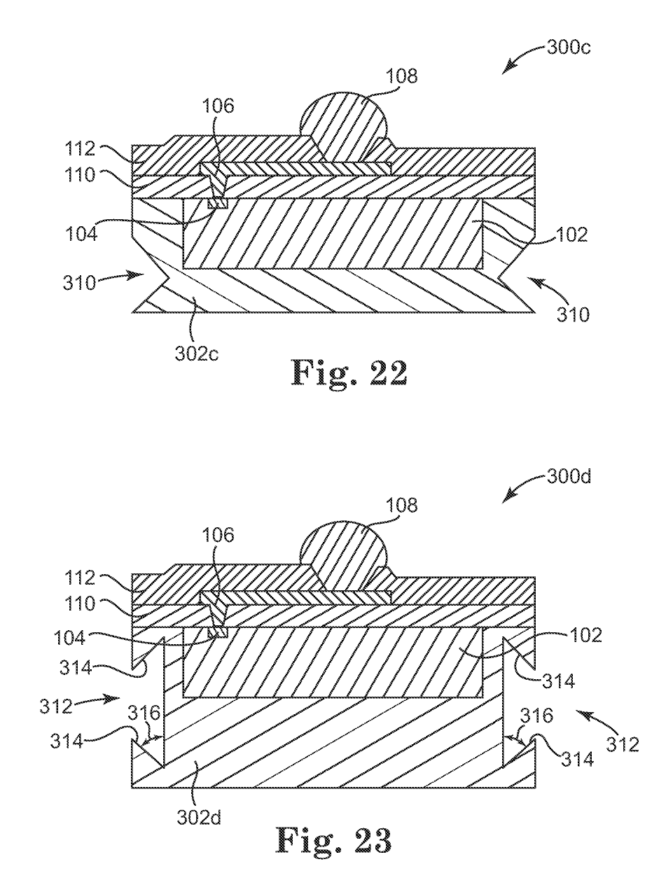

FIG. 22 illustrates a cross-sectional view of another embodiment of a semiconductor device 300c. Semiconductor device 300c is similar to semiconductor device 100a previously described and illustrated with reference to FIG. 1, except that in semiconductor device 300c, molded body 114a is replaced with molded body 302c. In one embodiment, molded body 302c includes a mold compound and is fabricated using a molding process. Molded body 302c includes at least one recess 310 on each sidewall of semiconductor device 300c. In one embodiment, each recess 310 has a triangular shape. Recesses 310 are configured for mechanically coupling semiconductor device 300c to another object. In one embodiment, the object is another semiconductor device, a cooling structure (e.g., cooling fins, cooling web), a mounting structure (e.g., clamp), or another suitable object. In one embodiment, recesses 310 provide a mechanical stop.

FIG. 23 illustrates a cross-sectional view of another embodiment of a semiconductor device 300d. Semiconductor device 300d is similar to semiconductor device 100a previously described and illustrated with reference to FIG. 1, except that in semiconductor device 300d, molded body 114a is replaced with molded body 302d. In one embodiment, molded body 302d includes a mold compound and is fabricated using a molding process followed by additional processing. In one embodiment, the additional processing includes laser cutting, sawing, lapping, grinding, milling, or shaping the mold compound using another suitable technique to provide at least one recess having a desired shape.

Molded body 302d includes at least one recess 312 on each sidewall of semiconductor device 300d. Each recess 312 includes sidewalls 314. In one embodiment, sidewalls 314 are slanted such that angle 316 is less than 90° and recess 312 has a sideways trapezoidal shape. Each Recess 312 is configured for mechanically coupling semiconductor device 300d to another object. In one embodiment, the object is another semiconductor device, a cooling structure, a mounting structure (e.g., a rail, a clamp, a clip), or another suitable object.

Embodiments provide a semiconductor device including a molded body having at least one recess that is configured for mechanically coupling the semiconductor device to another object. In one embodiment, the molded body is fabricated by using a molding process. In another embodiment, the molded body is fabricated by using a molding process followed by additional processing. In this way, the use of semiconductor devices fabricated using embedded wafer level ball grid array (eWLB) technology can expand into new applications.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device comprising:
a semiconductor chip;
at least one metal line over a first side of the semiconductor chip; and
a molded body covering at least a second side of the semiconductor chip, the molded body comprising at least one recess.

2. The semiconductor device of claim 1, wherein the at least one recess is configured for mechanically coupling the semiconductor device to an object.

3. The semiconductor device of claim 1, wherein the at least one recess is one of trapezoidal in shape, rectangular in shape, triangular in shape, square shaped, and T-shaped.

4. The semiconductor device of claim 1, wherein the at least one metal line is over the molded body, and
wherein the at least one recess is configured for receiving a fiber optic cable.

5. The semiconductor device of claim 1, wherein the at least one recess is configured for receiving one of a cooling structure, another semiconductor device, and a mounting structure.

6. The semiconductor device of claim 1, wherein the at least one recess is plated with a metal.

7. A semiconductor device package comprising:
a semiconductor chip;
at least one solder bump coupled to a first side of the semiconductor chip; and
a molded body covering at least a second side of the semiconductor chip opposite the first side, the molded body comprising means for mechanically coupling the semiconductor device package to an object.

8. The semiconductor device package of claim 7, wherein the object comprises one of a fiber optic cable, a cooling structure, another semiconductor device package, and a mounting structure.

9. A semiconductor device comprising:
a semiconductor die;
a solder ball coupled to a first side of the semiconductor die; and
a mold material over a second side of the semiconductor die, the mold material defining at least one recess.

10. The semiconductor device of claim 9, wherein the mold material defines a plurality of recesses.

11. The semiconductor device of claim 9, wherein the second side is perpendicular to the first side.

12. The semiconductor device of claim 9, wherein the at least one recess is configured for mechanically coupling the semiconductor device to an object.

13. The semiconductor device of claim 9, wherein the at least one recess is one of trapezoidal in shape, rectangular in shape, triangular in shape, square shaped, and T-shaped.

14. The semiconductor device of claim 9, wherein the at least one recess is configured for coupling to one of a winding, a thread, and a worm.

15. The semiconductor device of claim 9, wherein the at least one recess is configured for coupling to one of a clamp, a clip, and a rail.

16. A method for fabricating a semiconductor device, the method comprising:
providing a semiconductor chip;
applying a mold material over at least a first side of the semiconductor chip;
shaping the mold material such that at least one recess is formed in the mold material; and
applying a metal layer over a second side of the semiconductor chip and the mold material.

17. The method of claim 16, wherein shaping the mold material comprises shaping the mold material such that the at least one recess is one of trapezoidal in shape, rectangular in shape, triangular in shape, square shaped, and T-shaped.

18. The method of claim 16, wherein shaping the mold material comprises one of cutting, sawing, lapping, grinding, and milling the mold material.

19. The method of claim 16, wherein shaping the mold material comprises shaping the mold material such that the at least one recess is configured for receiving a fiber optic cable.

20. The method of claim 16, wherein shaping the mold material comprises shaping the mold material such that the at least one recess is configured for receiving one of a cooling structure, another semiconductor device, and a mounting structure.

21. The method of claim 16, further comprising:
plating at least a portion of the mold material with a metal.

22. A method for fabricating a semiconductor device, the method comprising:
providing a semiconductor die;
applying a mold material over at least a first side of the semiconductor die;
forming at least one recess in the mold material; and
coupling a solder ball to a second side of the semiconductor die.

23. The method of claim 22, wherein forming the at least one recess comprises one of cutting, sawing, lapping, grinding, and milling the mold material.

24. The method of claim 22, wherein forming the at least one recess comprises molding the mold material.

25. The method of claim 22, wherein forming the at least one recess comprises forming a plurality of recesses.
